(19) United States
(12) Patent Application Publication
(10) Pub. No.: US 2018/0240918 A1
(43) Pub. Date: Aug. 23, 2018

(54) PHOTOVOLTAIC DEVICES INCLUDING A CHALCOGENIDE-CONTAINING PHOTOVOLTAIC LIGHT-ABSORBER, AND RELATED METHODS OF MAKING

(71) Applicants: DOW GLOBAL TECHNOLOGIES LLC, Midland, MI (US); NUVOSUN, INC., Milpitas, CA (US)

(72) Inventors: Brian GOODFELLOW, Midland, MI (US); Puthur D. PAULSON, Milpitas, CA (US)

(21) Appl. No.: 15/749,734

(22) PCT Filed: Aug. 1, 2016
(86) PCT No.: PCT/US2016/045001

§ 371 Date: Feb. 1, 2018

Related U.S. Application Data
(60) Provisional application No. 62/201,374, filed on Aug. 5, 2015.

(51) Int. Cl. H01L 31/0392; H01L 31/18; H01L 31/032; H01L 31/0749

(52) U.S. Cl. CPC H01L 31/03928; H01L 31/0749; H01L 31/0323; H01L 31/18

(57) ABSTRACT

The present disclosure relates to photovoltaic devices that include a chalcogenide-containing photovoltaic light-absorber having a composition profile defined by at least a first region, a second region, and a third region. The second region is located between the first region and the third region. Each region of the chalcogenide-containing photovoltaic light-absorber includes Cu, In, Ga, Al, and at least one chalcogen. The concentration of Al present in the second region is less than the concentration of Al present in each of the first region and third region. Methods of making such chalcogenide-containing photovoltaic light-absorbers are also disclosed.

### RELATED APPLICATION

The present application claims the benefit of commonly owned provisional Application having Ser. No. 62/201,374, filed on Aug. 5, 2015, which provisional application is incorporated herein by reference in its entirety.

### TECHNICAL FIELD

The present disclosure relates to chalcogenide-containing photovoltaic light-absorbers, photovoltaic devices that incorporate such absorbers, and related methods of making chalcogenide-containing photovoltaic light-absorbers.

### BACKGROUND

Chalcogenide-containing photovoltaic light-absorbers have photovoltaic functionality (also referred to herein as photoabsorbing functionality). These materials can absorb incident light and generate an electric output when incorporated into a photovoltaic device. Consequently, chalcogenide-containing photovoltaic light-absorbers have been used as the photovoltaic absorber region in functioning photovoltaic devices. The composition of a chalcogenide-containing photovoltaic light-absorber can determine its electronic bandgap. And the electronic bandgap of a chalcogenide-containing photovoltaic light-absorber can impact the portion of the solar spectrum that can be converted into electricity, and the energy that can be extracted from each photon of light. Accordingly, the bandgap of a chalcogenide-containing photovoltaic light-absorber in a photovoltaic device can impact the overall energy that is converted from the solar spectrum. Chalcogenide-containing photovoltaic light-absorbers and photovoltaic devices including the same are known. See, e.g., U.S. Pat. No. 8,198,117 (Leidholm et al.); U.S. Pat. No. 8,197,703 (Basol); U.S. Pat. No. 8,846,438 (Yen et al.); and U.S. Pat. No. 8,993,882 (Gerbi et al.). See also, e.g., U.S. Publication No. 20100236629 (Chuang). See also, e.g., foreign patent document numbers JP 2011155146 A, (Takeshi); KR 2011046196 A, (Sun); JP 04919710 B2, (Hashimoto et al.); and WO 2011115894 A1; (Gerbi et al.). See also, e.g., S. Marsillac et al., High-efficiency solar cells based on Cu(InAl)Se₂ thin films, Applied Physics Letters 81 (2002) 1350-1352; D-C. Perng et al., Formation of CuInAlSe₂ film with double graded bandgap using Mo(Al) back contact, Solar Energy Materials & Solar Cells 95 (2011) 257-260; and C-L. Wang et al., Anti-Corroded Molybdenum Back Electrodes by Al Doping for CuIn₁₋ₓAlₓSe₂ Solar Cells, Journal of The Electrochemical Society 158(7) (2011) C231-C235. There is a continuing desire for new chalcogenide-containing photovoltaic light-absorbers, and methods of making the same.

### SUMMARY

Embodiments of the present disclosure include a photovoltaic device that includes:

a) a substrate;

b) a first electrode located over the substrate;

c) at least one chalcogenide-containing photovoltaic light-absorber located over and electrically connected to the first electrode; wherein the chalcogenide-containing photovoltaic light-absorber has a composition profile defined by at least a first region, a second region, and a third region; wherein the first region is located proximal to the first electrode, the second region is located between the first region and the third region, and the third region is located distal to the first electrode; wherein each region of the chalcogenide-containing photovoltaic light-absorber includes Cu, In, Ga, Al, and at least one chalcogen; and wherein the concentration of Al present in the second region is less than the concentration of Al present in each of the first region and third region;

d) an n-type semiconductor region located over the at least one chalcogenide-containing photovoltaic light-absorber; and

e) a second electrode located over the n-type semiconductor region.

Embodiments of the present disclosure also include a method of processing a chalcogenide-containing photovoltaic light-absorber or a photovoltaic light-absorber precursor, comprising the steps of:

a) providing a stack comprising:
i) a substrate;
ii) a first electrode precursor located over the substrate, wherein the first electrode precursor includes at least one layer comprising aluminum; and
iii) at least one layer located over the first electrode precursor, wherein the at least one layer comprises a chalcogenide-containing photovoltaic light-absorber comprising copper, indium, gallium, and at least one chalcogen, or a photovoltaic light-absorber precursor comprising copper, indium, gallium, and optionally a sub-stoichiometric amount of at least one chalcogen; and

b) a heating step comprising heating the stack to diffuse at least a portion of the aluminum into the at least one layer of the absorber or the absorber precursor.

### BRIEF DESCRIPTION OF THE DRAWINGS

FIG. 1 is a schematic cross-section of an embodiment of a photovoltaic device according to the present disclosure;

FIG. 2 is a schematic cross-section and flow diagram illustrating an embodiment of a method of making a chalcogenide-containing photovoltaic light-absorber according to the present disclosure; and

FIG. 3 is a schematic cross-section and flow diagram illustrating another embodiment of a method of making a chalcogenide-containing photovoltaic light-absorber according to the present disclosure.

FIG. 4 shows x-ray diffraction data of stacks of comparative example A and examples 1, 2, and 3, where the stacks include a substrate, first electrode, and chalcogenide-containing photovoltaic light absorber.

FIG. 5 shows secondary ion mass spectroscopy data of comparative example A.

FIG. 6 shows secondary ion mass spectroscopy data of example 3.

FIG. 7 shows x-ray diffraction data of the photovoltaic devices of comparative example B and examples 4 and 5.

FIG. 8 shows current-voltage data of the photovoltaic devices of comparative example B and examples 4 and 5.

FIG. 9 shows secondary ion mass spectroscopy data of comparative example B.

FIG. 10 shows secondary ion mass spectroscopy data of example 4.

FIG. 11 shows secondary ion mass spectroscopy data of example 5.

### DETAILED DESCRIPTION

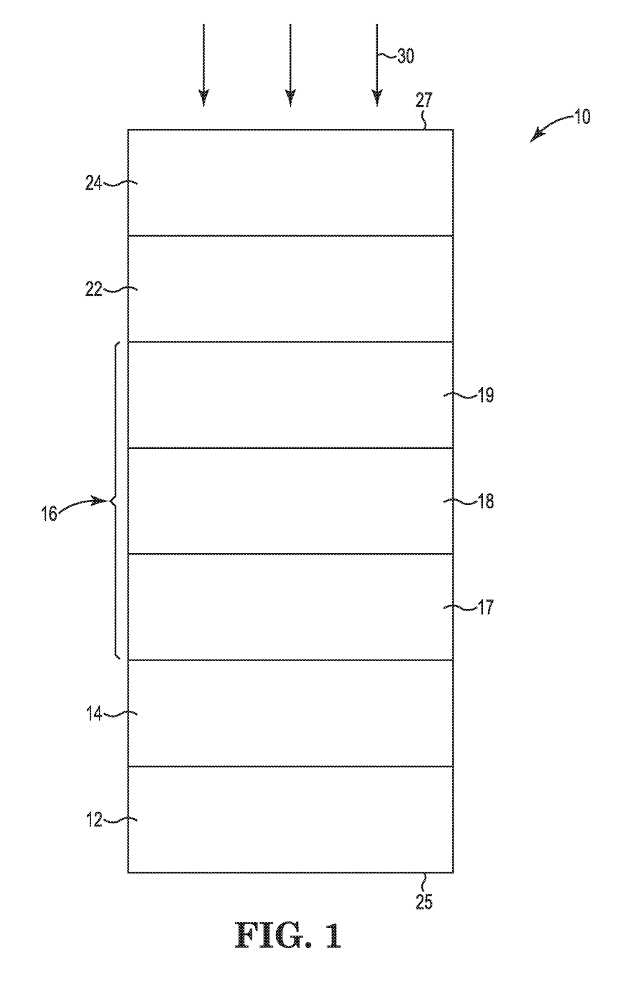

A photovoltaic device according to the present disclosure includes a substrate; a first electrode, at least one chalcogenide-containing photovoltaic light-absorber, an n-type semiconductor region, and a second electrode. An exemplary embodiment of a photovoltaic device 10 according to the present disclosure is illustrated in FIG. 1, and is described herein below in more detail.

As used herein below, “at %” means atomic percent.

As shown in FIG. 1, photovoltaic device 10 includes a substrate 12, a first electrode 14, a chalcogenide-containing photovoltaic light-absorber 16, an n-type semiconductor region 22, and a second electrode 24.

Device 10 desirably is flexible to allow it to be mounted to surfaces incorporating some curvature.

As shown in FIG. 1, device 10 includes a light incident face 27 that receives light rays 30 and a backside face 25.

Substrate 12 may be rigid or flexible, but desirably is flexible in embodiments in which the device 10 may be used in combination with non-flat surfaces. Substrate 12 may be formed from a wide range of materials. These include glass, quartz, other ceramic materials, polymers, metals (e.g., flexible metal foil), metal alloys, intermetallic compositions, paper, woven or non-woven fabrics, combinations of these, and the like. In one exemplary embodiment, substrate 12 is formed from stainless steel. In some embodiments, substrate 12 includes no more than 10 atomic percent (at %) aluminum (Al), e.g., less than 5 at %, or even less than 1 at % Al.

Substrate 12 can include one or more layers (e.g., one or more metal layers). Substrate 12 can have any desired thickness depending on the context that device 10 is being used in. In some embodiments, substrate 12 can have a total thickness of 0.1 mils or more, 0.5 mils or more, or even 1 mil or more. In some embodiments, substrate 12 can have a total thickness of 10 mils or less, or even 5 mils or less (e.g., 2 mils).

As shown in FIG. 1, first electrode 14 is located over the substrate 12. The first electrode 14 can provide a convenient way to electrically couple photovoltaic device 10 to external circuitry. The first electrode 14 can also help isolate the chalcogenide-containing photovoltaic light-absorber 16 from the substrate 12 so as to help minimize any migration of substrate 12 constituents into the chalcogenide-containing photovoltaic light-absorber 16. For instance, first electrode 14 can help to block the migration of Fe and Ni constituents that may be present in a stainless steel substrate 12 into the chalcogenide-containing photovoltaic light-absorber 16. The first electrode 14 can also help protect the substrate 12 such as by protecting against Se if Se is used in the formation of chalcogenide-containing photovoltaic light-absorber 16.

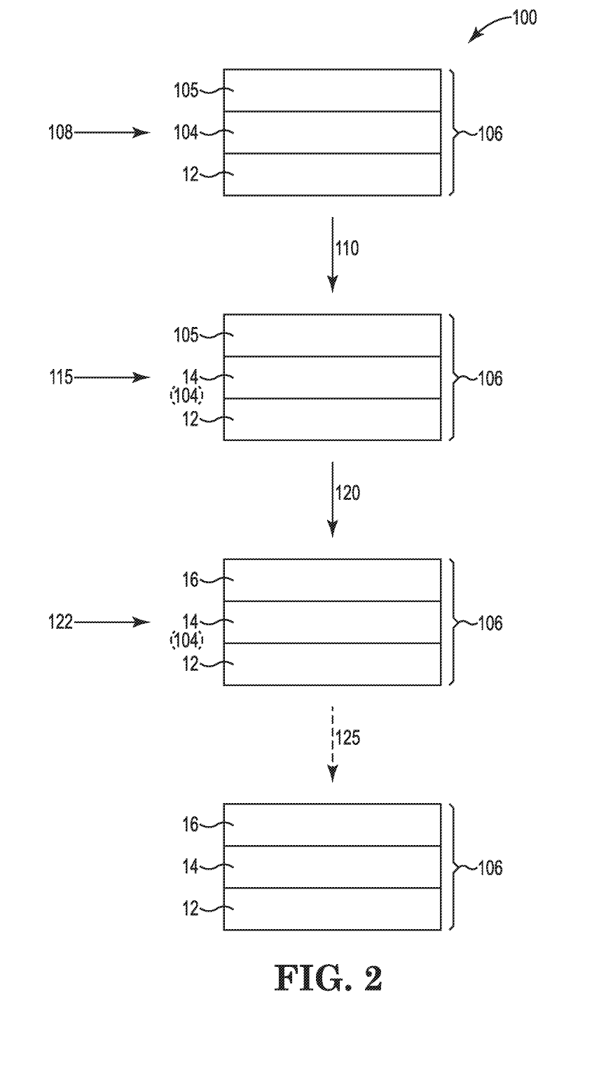

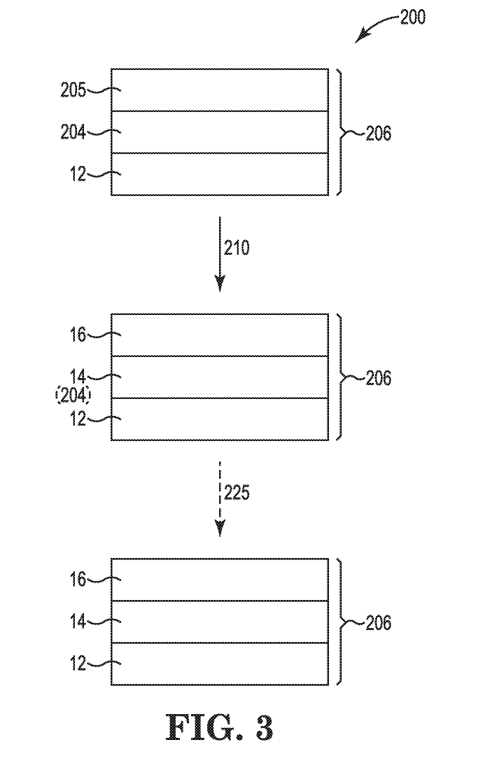

First electrode 14 may be formed from a wide range of electrically conductive materials, including one or more of Mo, W, Nb, Ta, Cr, Ti, Al, nitrides thereof, and combinations thereof, and the like. In some embodiments, first electrode 14 can be deposited on substrate 12 by a sputtering process. As discussed below in connection with FIGS. 2 and 3, in some embodiments an amount Al may be present in first electrode 14 because it is “left over” after heating stack 106 to diffuse Al from first electrode precursors 104 or 204 into the photovoltaic light-absorber precursors 105 or 205, respectively (and, optionally, the chalcogenide-containing photovoltaic light-absorber 16). In some embodiments, the first electrode 14 can include one or more layers that contain a material chosen from Mo, W, Nb, Ta, Cr, Ti, Al, nitrides thereof, and combinations thereof. Referring to FIGS. 2 and 3, if different materials are used to form first electrode precursors 104 and 204, the different materials may be in the same layer or layers or different materials may be in distinct layers. In some embodiments, first electrode precursors 104 and 204 can include one layer formed by co-sputtering Al with Mo, W, Nb, Ta, Cr, Ti, nitrides thereof, and combinations thereof. For example, first electrode precursors 104 and 204 can include at least one layer formed by co-sputtering Al and Mo. In some embodiments, the composition of such a co-sputtered layer can be represented by the chemical formula Mo₁₋ᵥAlᵥ where “v’ is 0.01 or greater, or even 0.1 or greater. In some embodiments, “v” is 0.50 or less, or even 0.20 or less. In alternative embodiments, first electrode precursors 104 and 204 can include a multilayer structure. An example of a multilayer structure includes at least one Ti layer and at least one Mo layer. Another example of a multilayer structure includes a layer of Al between two layers of Mo. Such an alternative embodiment may be desired for subsequent heating (discussed below in connection with FIGS. 2 and 3) to cause at least a portion of the Al to diffuse from first electrode precursors 104 and 204 into photovoltaic light-absorber precursors 105 or 205, respectively (and, optionally, the chalcogenide-containing photovoltaic light-absorber 16).

First electrode 14 can be formed from first electrode precursors 104 or 204 that are made by a physical vapor deposition technique such as sputtering.

Sputtering can be performed at a wide variety of conditions. In some embodiments, sputtering can be performed in an atmosphere of an inert gas such as argon. In some embodiments, sputtering can be performed in an atmosphere having a pressure of 0.1 mtorr or more, or even 1 mtorr or more. In some embodiments, sputtering can be performed in an atmosphere having a pressure of 20 mtorr or less, or even 5 mtorr or less. In some embodiments, sputtering can be performed while substrate 12 is at a temperature of 20° C. or more, or even 25° C. or more. In some embodiments, sputtering can be performed while substrate 12 is at a temperature of 500° C. or less, or even at a temperature of 350° C. or less.

First electrode 14 can have any desired thickness. In some embodiments, first electrode 14 can have a thickness of at least 0.05 μm, at least 0.1 μm, or even at least 0.5 μm. In some embodiments, first electrode 14 can have a thickness of 5 μm or less, 2 μm or less, or even 1 μm or less.

In some embodiments, a layer or multilayer structure (not shown) can function as both a substrate and a first electrode.

As shown in FIG. 1, chalcogenide-containing photovoltaic light-absorber 16 is located over and electrically connected to the first electrode 14. The chalcogenide-containing photovoltaic light-absorber 16 can absorb light energy embodied in the light rays 30 and then photovoltaically convert the light energy into electric energy. As shown in FIG. 1, the chalcogenide-containing photovoltaic light-absorber 16 has a composition profile defined by at least a first region 17, a second region 18, and a third region 19. As shown in FIG. 1, the first region 17 is located proximal to the first electrode 14, the second region 18 is located between the first region 17 and the third region 19, and the third region 19 is located distal to the first electrode 14. Each region (17, 18, and 19) of the chalcogenide-containing photovoltaic light-absorber 16 includes copper (Cu), indium (In), gallium (Ga), aluminum (Al), and at least one chalcogen. The concentration of Al present in the second region 18 is less than the concentration of Al present in each of the first region 17 and third region 19. Such a concentration profile of Al in the chalcogenide-containing photovoltaic light-absorber 16 can be referred to as a “double gradient” of aluminum concentration and can result in a double electronic bandgap gradient. Such a bandgap profile can increase solar power conversion efficiency by simultaneously providing increased current and voltage in a photovoltaic cell when compared to an analogue having an absorber layer of uniform bandgap. The total amount of Al in a region can depend on one or more factors such as porosity, density, and the like of the chalcogenide-containing photovoltaic light-absorber 16. The at least one chalcogen can be chosen from selenium (Se), sulfur (S), tellurium (Te), and combinations thereof.

In some embodiments, the chalcogenide-containing photovoltaic light-absorber 16 in the first region 17 is represented by the chemical formula Cuₐ₁In_{b1}Ga_{c1}Al_{d1}Se_{w1}Sₓ₁Te_{y1}Na_{z1}, wherein 0.75≤a1≤1.10, 0.00≤b1≤0.84, 0.15≤c1≤0.70, 0.01≤d1≤0.35, 0.00≤w1≤3.00, 0.00x1≤3.00, 0.00≤y1≤3.00, 0.00≤z1≤0.05, b1+c1+d1=1, and 1.00≤w1+x1+y1≤3.00; the chalcogenide-containing photovoltaic light-absorber in the second region 18 is represented by the chemical formula Cuₐ₂In_{b2}Ga_{c2}Al_{d2}Se_{w2}Sₓ₂Te_{y2}Na_{z2}, wherein 0.75≤a2≤1.10, 0.00≤b2≤0.97, 0.02≤c2≤0.70, 0.01≤d2≤0.35, 0.00≤w2≤3.00, 0.00≤x2≤3.00, 0.00≤y2≤3.00, 0.00≤z2≤0.05, b2+c2+d2=1, and 1.00≤w2+x2+y2≤3.00; the chalcogenide-containing photovoltaic light-absorber in the third region 19 is represented by the chemical formula Cuₐ₃In_{b3}Ga_{c3}Al_{d3}Se_{w3}Sₓ₃Te_{y3}Na_{z3}, wherein 0.75≤a3≤1.10, 0.35≤b350.97, 0.02≤c3≤0.30, 0.01≤d30.35, 0.00≤w3≤3.00, 0.00≤x3≤3.00, 0.00≤y353.00, 0.00≤z3≤0.05, b3+c3+d3=1, and 1.00≤w3+x3+y3≤3.00; wherein d2<d1; and wherein d2<d3. For each region the average value of either d1, d2, or d3 can be expressed by d1a, d2a, or d3a, respectively. In some embodiments, the ratio d2a/d1a can be 0.03 or greater, or even 0.10 or greater. In some embodiments, the ratio d2a/d1a can be 0.90 or less, or even 0.60 or less. In some embodiments, the ratio d2a/d3a can be 0.03 or greater, or even 0.15 or greater. In some embodiments, the ratio d2a/d3a can be 0.90 or less, or even 0.75 or less. In some embodiments, c1>c2>c3.

Optionally, the chalcogenide-containing photovoltaic light-absorber 16 can be doped with one or more materials such as sodium (Na), potassium (K), and the like.

In some embodiments, the chalcogenide-containing photovoltaic light-absorber 16 includes Ga in an amount of at least 0.4 atomic percent, at least 0.5 atomic percent, at least 0.6 atomic percent, at least 0.7 atomic percent, at least 0.8 atomic percent, at least 0.9 atomic percent, or even 1.0 atomic percent based on the total chalcogenide-containing photovoltaic light-absorber 16.

The composition profile of the chalcogenide-containing photovoltaic light-absorber 16 can define a bandgap profile of the chalcogenide-containing photovoltaic light-absorber 16. In some embodiments, the chalcogenide-containing photovoltaic light-absorber layer can include a chalcopyrite-type semiconductor alloy represented by the chemical formula Cu(InₓGa_{y}Al_{z})Se₂ (also referred to as “CIGAS”), where x+y+z=1. The corresponding electronic bandgap of Cu(InₓGa_{y}Al_{z})Se₂ can be estimated by the equation E_{g}^{CIGAS}=xEg^{CIS}+yE_{g}^{CGS}+zE_{g}^{CAS}−b^{CIGS}xy−b^{CIAS}xz−b^{CGAS}yz, where the bandgaps E_{g} of the alloy endpoints CuInSe₂, CuGaSe₂, and CuAlSe₂ are E_{g}^{CIS}=1.0 eV, E_{g}^{CGS}=1.7 eV, and E_{g}^{CAS}=2.7 eV, respectively, and where the optical bowing coefficients, b, for Cu(In,Ga)Se₂, Cu(In,Al)Se₂, and Cu(Ga,Al)Se₂ are b^{CIGS}=0.2 eV, b^{CIAS}=0.6 eV, and b^{CGAS}=0.4 eV, respectively. In some embodiments, the first region 17 has a bandgap of at least 1.09 eV, or even at least 1.15 eV. In some embodiments, the first region 17 has a bandgap of 1.96 eV or less, or even 1.45 eV or less. In some embodiments, the second region 18 has a bandgap or at least 1.02 eV, or even at least 1.05 eV. In some embodiments, the second region 18 has a bandgap 1.96 eV or less, or even 1.35 eV or less. In some embodiments, the third region 19 has a bandgap of at least 1.02 eV, or even at least 1.10 eV. In some embodiments, the third region 19 has a bandgap of 1.67 eV or less, or even 1.40 eV or less. The chalcogenide-containing photovoltaic light-absorber 16 can have any desired thickness. In some embodiments, the chalcogenide-containing photovoltaic light-absorber 16 has a total thickness (T), the first region has a thickness (t1), the second region has a thickness (t2), and the third region has a thickness (t3); wherein T is at least 0.1 micrometers, or even at least 0.25 micrometers. In some embodiments, T is 10 micrometers or less, or even 5 micrometers or less. In some embodiments, 0.1*T≤t1, 0.1*T≤t2≤0.8*T, and 0.1*T≤t3.

Embodiments of the present disclosure include methods of processing a chalcogenide-containing photovoltaic light-absorber or a photovoltaic light-absorber precursor. Such methods include providing a stack and heating the stack to diffuse at least a portion of aluminum from a first electrode precursor into at least one layer of an absorber or an absorber precursor. The stack includes a substrate; a first electrode precursor located over the substrate and having at least one layer that includes aluminum; and at least one layer located over the first electrode precursor and having a chalcogenide-containing photovoltaic light-absorber that includes copper, indium, gallium, and at least one chalcogen, or a photovoltaic light-absorber precursor that includes copper, indium, gallium, and optionally a sub-stoichiometric amount of at least one chalcogen. Optionally, where the at least one layer located over the first electrode precursor includes a photovoltaic light-absorber precursor that has copper, indium, gallium, and optionally a sub-stoichiometric amount of at least one chalcogen, a method according to the present disclosure can further include a second heating step to heat the stack in the presence of at least one chalcogen to convert at least a portion of the photovoltaic light-absorber precursor into a chalcogenide-containing photovoltaic light-absorber. Such first and second heating steps can be performed sequentially, simultaneously, or in an overlapping manner.

Exemplary methods of processing a chalcogenide-containing photovoltaic light-absorber and/or a photovoltaic light-absorber precursor according to the present disclosure are illustrated and described with respect to FIGS. 2 and 3.

FIG. 2 illustrates a method 100 that includes heating a stack to cause at least diffusion of aluminum from a first electrode precursor into a photovoltaic light-absorber precursor followed by heating the stack in the presence of at least one chalcogen to cause at least conversion of the photovoltaic light-absorber precursor into chalcogenide-containing photovoltaic light-absorber. Optionally, the stack may be heated after conversion of the photovoltaic light-absorber precursor into chalcogenide-containing photovoltaic light-absorber so as to cause diffusion of an additional amount of aluminum from the first electrode precursor into the chalcogenide-containing photovoltaic light-absorber. After diffusion of the desired amount of aluminum out of the first electrode precursor is complete, the first electrode precursor is referred to herein as the first electrode even though the first electrode may have some aluminum content remaining.

As shown in FIG. 2, a stack 106 is provided at stage 108 and includes substrate 12, first electrode precursor 104, and a photovoltaic light-absorber precursor 105.

At stage 108, the first electrode precursor 104 is located over substrate 12 and includes at least one layer having aluminum. The aluminum is provided in an amount to help provide the desired concentration profile of aluminum in the chalcogenide-containing photovoltaic light-absorber 16 discussed above. In some embodiments, first electrode precursor 104 is made by co-sputtering Al with a material chosen from Mo, W, Nb, Ta, Cr, Ti, nitrides thereof, and combinations thereof. The precursor of the at least one chalcogenide-containing photovoltaic light-absorber 105 is deposited on the first electrode precursor 104. At stage 108, the photovoltaic light-absorber precursor 105 includes at least copper, indium, gallium, and optionally at least one chalcogen. Because the elements Cu, In, and Ga (and optionally a sub-stoichiometric amount of at least one chalcogen) tend to react, the precursor 105 at stage 108 may include trace amounts of photovoltaic light-absorber material or chalcogenide-containing photovoltaic light-absorber material. The photovoltaic light-absorber precursor 105 can be deposited on first electrode precursor 104 via sputtering. For example, the photovoltaic light-absorber precursor 105 can be sputtered from targets including In, Cu—Ga, Cu—In—Ga, or any combination or ordering thereof.

In some embodiments, the photovoltaic light-absorber precursor 105 can be sputtered in an atmosphere that includes at least one chalcogen (e.g., Se, S, Te, and combinations thereof). The photovoltaic light-absorber precursor 105 in stage 108 may include a sub-stoichiometric amount of at least one chalcogen such as Se. In some embodiments, photovoltaic light-absorber precursor 105 can have at least one chalcogen (e.g., Se) present in a sub-stoichiometric amount of 10 at % or more, or even 20 at % or more. In some embodiments, photovoltaic light-absorber precursor 105 can have at least one chalcogen (e.g., Se) present in a sub-stoichiometric amount of 40 at % or less, or even 30 at % or less.

The photovoltaic light-absorber precursor 105 can have any desired thickness. In some embodiments, the precursor of the photovoltaic light-absorber precursor 105 can have a thickness of 0.2 μm or more, or even 0.5 μm or more. In some embodiments, the precursor of the photovoltaic light-absorber precursor 105 can have a thickness of 1.5 μm or less, or even 1 μm or less.

In some embodiments, the photovoltaic light-absorber precursor 105 at stage 108 (i.e., prior to heating in steps 110, 120, and optionally 125) may include no aluminum or a trace amount of Al due to, e.g., an impurity. For example, the photovoltaic light-absorber precursor 105 at stage 108 may have an aluminum content of no more than 0.5 at %, no more than 0.1 at %, no more than 0.05 at %, or even no more than 0.005 at %.

Alternatively, a chalcogenide-containing photovoltaic light-absorber (not shown) could be formed on first electrode precursor 104 instead of photovoltaic light-absorber precursor 105. The chalcogenide-containing photovoltaic light-absorber can include copper, indium, gallium, and at least one chalcogen. The copper, indium, gallium, and at least one chalcogen could be formed by reactive sputtering or co-evaporation.

As shown in FIG. 2, the stack 106 is subjected to a heating step 110 to cause at least a portion of the aluminum from the first electrode precursor 104 to diffuse into the photovoltaic light-absorber precursor 105. In some embodiments, the stack 106 can be heated during step 110 to a temperature of 50° C. or more, 100° C. or more, 200° C. or more, or even 300° C. or more. In some embodiments, the stack 106 can be heated during step 110 to a temperature of 650° C. or less, 600° C. or less, 550° C. or less, 500° C. or less, 450° C. or less, or even 400° C. or less. The stack 106 can be heated for a time period so as to diffuse a desired amount of aluminum from first electrode precursor 104 into the photovoltaic light-absorber precursor 105. In some embodiments, the stack 106 can be held at any desired temperature for a time period of 1 minute or more, or even 5 minutes or more. In some embodiments, the stack 106 can be held at any desired temperature for a time period of 90 minutes or less, 80 minutes or less, or even 60 minutes or less.

As shown in FIG. 2, at least a portion of the Al in the first electrode precursor 104 from stage 108 has diffused into the photovoltaic light-absorber precursor 105 at stage 115 due to the heating step 110. Heating step 110 can diffuse aluminum into the photovoltaic light-absorber precursor 105 so that the concentration of Al can form a gradient within the photovoltaic light-absorber precursor 105 and ultimately the chalcogenide photovoltaic light-absorber 16 formed in heating step 120 (discussed below).

Next, as also shown in FIG. 2, the stack 106 can be heated at step 120 in the presence of at least one chalcogen (e.g., Se, S, Te, and combinations thereof) to convert at least a portion of photovoltaic light-absorber precursor 105 into the chalcogenide-containing photovoltaic light-absorber 16. In some embodiments, the stack 106 can be heated to a temperature during heating step 120 to a temperature of 450° C. or more, 500° C. or more, 525° C. or more, or even 575° C. or more. In some embodiments, the stack 106 can be heated to a temperature during heating step 120 to a temperature of 650° C. or less, or even 600° C. or less. The stack 106 can be heated in the presence of at least one chalcogen and held at a desired temperature for a time period to convert at least a portion of photovoltaic light-absorber precursor 105 into the chalcogenide-containing photovoltaic light-absorber 16. In some embodiments, the stack 106 can be held at a desired temperature for a time period of 1 minute or more, or even 5 minutes or more. In some embodiments, the stack 106 can be held at a desired temperature for a time period of 90 minutes or less, 25 minutes or less, 15 minutes or less, or even 10 minutes or less.

The heating steps 110 and 120 can involve a variety of heating protocols. For example, the heating step 110 can involve ramping up the temperature of the stack 106 from a relatively low temperature (e.g., 25° C.) to a first target temperature (e.g., less than 450° C.) where the first target temperature is held for a first time period to diffuse a desired amount of aluminum from the first electrode precursor 104 into the photovoltaic light-absorber precursor 105. After the first time period, heating step 120 can involve ramping up the temperature of the stack 106 from the first target temperature to a second target temperature (e.g., 450° C. or greater) where the second target temperature is held for a second time period to convert at least a portion of photovoltaic light-absorber precursor 105 into the chalcogenide-containing photovoltaic light-absorber 16. Such a protocol is considered a “sequential” heating protocol. Optionally, a cooldown period can be performed in between steps 110 and 120.

Because the stack 106 can be heated at step 120 in the presence of at least one chalcogen (e.g., Se, S, Te, and combinations thereof), the atomic percentage of the at least one chalcogen in the chalcogenide-containing photovoltaic light-absorber 16 can be increased with respect to the atomic percentage of the at least one chalcogen in the photovoltaic light-absorber precursor 105.

The stack 106 can be heated at step 120 in an atmosphere at any desired pressure. In some embodiments, the stack 106 can be heated at step 120 in an atmosphere having a pressure of 0.1 mtorr or more, or even 0.5 mtorr or more (e.g., even at atmospheric pressure). In some embodiments, the stack 106 can be heated at step 120 in an atmosphere having a pressure of 10 mtorr or less, or even 5 mtorr or less.

As shown in FIG. 2, at stage 122 at least a portion (e.g., substantially all) of the photovoltaic light-absorber precursor 105 has been converted into the chalcogenide-containing photovoltaic light-absorber 16 due to the heating step 120. It is noted that during heating step 120, at least a portion of the first electrode precursor 104 (indicated by dotted lines) or first electrode 14 may be chalcogenized such that a chalcogenide layer (e.g. MoSe₂) (not shown) ranging in thickness from 1 nm to 1000 nm is formed between the first electrode precursor 104 or first electrode 14 and the chalcogenide-containing photovoltaic light-absorber 16.

Further, it is noted that temperature ranges in steps 110 and 120 can at least partially overlap (and hence the heating steps 110 and 120 are considered “overlapping”) so that diffusion of aluminum from the first electrode 104 may occur during heating step 120 when the stack 106 is heated in the presence of at least one chalcogen to convert at least a portion of photovoltaic light-absorber precursor 105 into the chalcogenide-containing photovoltaic light-absorber 16. Likewise, conversion of at least a portion of photovoltaic light-absorber precursor 105 into the chalcogenide-containing photovoltaic light-absorber 16 may occur during heating step 110.

In some embodiments, an amount of aluminum may still be present in first electrode 14 after heating step 120. Optionally, as shown by the dotted lines around reference characters in FIG. 2, the stack 106 can be heated at step 125 to cause at least a portion of the aluminum from the first electrode precursor 104 to diffuse into the chalcogenide-containing photovoltaic light-absorber 16. In some embodiments, the stack 106 can be heated during step 125 to a temperature of 50° C. or more, 100° C. or more, 200° C. or more, or even 300° C. or more. In some embodiments, the stack 106 can be heated during step 125 to a temperature of 650° C. or less, 600° C. or less, 550° C. or less, 500° C. or less, 450° C. or less, or even 400° C. or less. The stack 106 can be heated for a time period so as to cause at least a portion of the aluminum from the first electrode precursor 104 to diffuse into the chalcogenide-containing photovoltaic light-absorber 16. In some embodiments, the stack 106 can be held at any desired temperature for a time period of 1 minute or more, or even 5 minutes or more. In some embodiments, the stack 106 can be held at any desired temperature for a time period of 90 minutes or less, 80 minutes or less, or even 60 minutes or less. Optionally, a cooldown period can be performed in between steps 120 and 125.

FIG. 3 illustrates a method 200 that includes heating in the presence of at least one chalcogen to simultaneously cause both conversion of the photovoltaic light-absorber precursor into chalcogenide-containing photovoltaic light-absorber and diffusion of aluminum from a first electrode precursor. Optionally, the stack may be heated after conversion of the photovoltaic light-absorber precursor into chalcogenide-containing photovoltaic light-absorber so as to cause diffusion of an additional amount of aluminum from the first electrode precursor into the chalcogenide-containing photovoltaic light-absorber. After diffusion of the desired amount of aluminum out of the first electrode precursor is complete, the first electrode precursor is referred to herein as the first electrode even though the first electrode may have some aluminum content remaining.

As shown in FIG. 3, the heating step 210 can involve ramping up the temperature of the stack 206 from a relatively low temperature (e.g., 25° C.) to a first target temperature (e.g., 550° C.) where the first target temperature is held for a first time period to simultaneously cause both conversion of the photovoltaic light-absorber precursor 205 into chalcogenide-containing photovoltaic light-absorber 16 and diffusion of aluminum from a first electrode precursor 204. In some embodiments, an amount of aluminum may still be present in first electrode 14 after heating step 210. Optionally, as shown by the dotted lines in FIG. 3, the stack 206 can be heated at step 225 to cause at least a portion of the aluminum from the first electrode precursor 204 to diffuse into the chalcogenide-containing photovoltaic light-absorber 16. In some embodiments, the stack 206 can be heated during step 225 to a temperature of 50° C. or more, 100° C. or more, 200° C. or more, or even 300° C. or more. In some embodiments, the stack 206 can be heated during step 225 to a temperature of 650° C. or less, 600° C. or less, 550° C. or less, 500° C. or less, 450° C. or less, or even 400° C. or less. The stack 206 can be heated for a time period so as to cause at least a portion of the aluminum from the first electrode precursor 204 to diffuse into the chalcogenide-containing photovoltaic light-absorber 16. In some embodiments, the stack 206 can be heated and held at a desired temperature for a time period of 1 minute or more, or even 5 minutes or more. In some embodiments, the stack 206 can be held at any desired temperature for a time period of 90 minutes or less, 80 minutes or less, or even 60 minutes or less. Optionally, a cooldown period can be performed in between steps 210 and 225.

As mentioned above with respect to first electrode 14, some aluminum may remain in the first electrode 14 after all of the heating steps in FIGS. 2 and 3 such that the first electrode 14 in photovoltaic device 10 has some remaining aluminum content present.

As shown in FIG. 1, an n-type semiconductor region 22 is located over the chalcogenide-containing photovoltaic light-absorber 16. N-type semiconductor region 22 can help form a p-n junction proximal to the interface between the n-type semiconductor region 22 and chalcogenide-containing photovoltaic light-absorber 16.

A wide range of n-type semiconductor materials may be used to form n-type semiconductor region 22. Illustrative materials include selenides, sulfides, and/or oxides of one or more of cadmium, zinc, lead, indium, tin, combinations of these and the like, optionally doped with materials including one or more of fluorine, sodium, combinations of these and the like. In some illustrative embodiments, the n-type semiconductor region 22 is a selenide and/or sulfide including cadmium and optionally at least one other metal such as zinc. Other illustrative embodiments would include sulfides and/or selenides of zinc. Additional illustrative embodiments may incorporate oxides of tin doped with material(s) such as fluorine. In some embodiments, the n-type semiconductor region 22 includes a buffer region having one or more layers that include at least one first element chosen from Cd and Zn, and at least one second element chosen from S, Se, O, and combinations thereof.

A wide range of methods, such as for example, chemical bath deposition, partial electrolyte treatment, chemical vapor deposition, physical vapor deposition, or other deposition techniques, can be used to form n-type semiconductor region 22.

N-type semiconductor region 22 can be a single integral layer as illustrated or can be formed from one or more layers. N-type semiconductor region 22 can desirably be thin enough to be used in flexible photovoltaic devices. Illustrative n-type semiconductor region 22 embodiments may have a thickness in the range from about 10 nm to about 300 nm, with a buffer region in the range from 10 nm to about 100 nm.

As shown in FIG. 1, a second electrode 24 is located over the n-type semiconductor region 22. The second electrode 24 can provide a convenient way to electrically couple photovoltaic device 10 to external circuitry. The second electrode 24 can include a wide variety of transparent conducting oxides (TCO) or combinations of these may be incorporated into the second electrode 24. Examples include fluorine-doped tin oxide, tin oxide, indium oxide, indium tin oxide (ITO), aluminum doped zinc oxide (AZO), zinc oxide, combinations of these, and the like. In some embodiments, the second electrode 24 includes at least one layer that includes a material chosen from zinc oxide (ZnO), aluminum-doped zinc oxide (ZnO:Al or AZO), indium tin oxide (ITO), and combination thereof. In one illustrative embodiment, the second electrode 24 is indium tin oxide. Second electrode 24 can be formed via sputtering or other suitable deposition technique. In many suitable embodiments, the second electrode 24 has a thickness in the range from about 10 nm to about 1500 nm, from about 100 nm to about 300 nm. These representative embodiments result in films that are sufficiently transparent to allow incident light to reach the chalcogenide-containing photovoltaic light-absorber 16.

Device 10 can optionally include one or more layers or regions that perform a variety of functions such as an electrically conducting collection grid or lines, one or more intervening layers for a variety of reasons such as to promote adhesion, enhance electrical performance, or the like.

In some embodiments, a collection grid (not shown) can include one or more electrical contacts (not shown) in electrical contact with the second electrode 24. Exemplary collection grid materials include one or more of Cu, Ni, Sn, Ag, combinations of these, and the like. In some embodiments, the collection grid can be in the form of a mesh.

### Comparative Example A

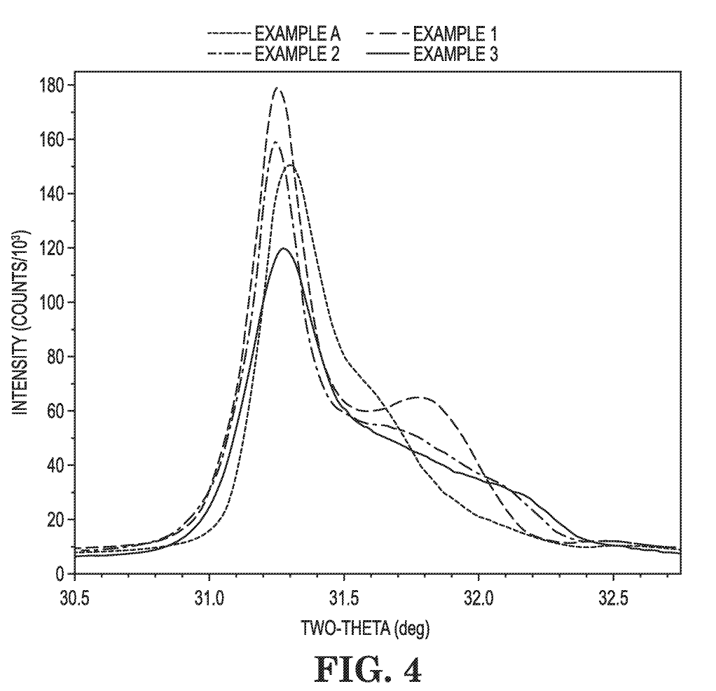

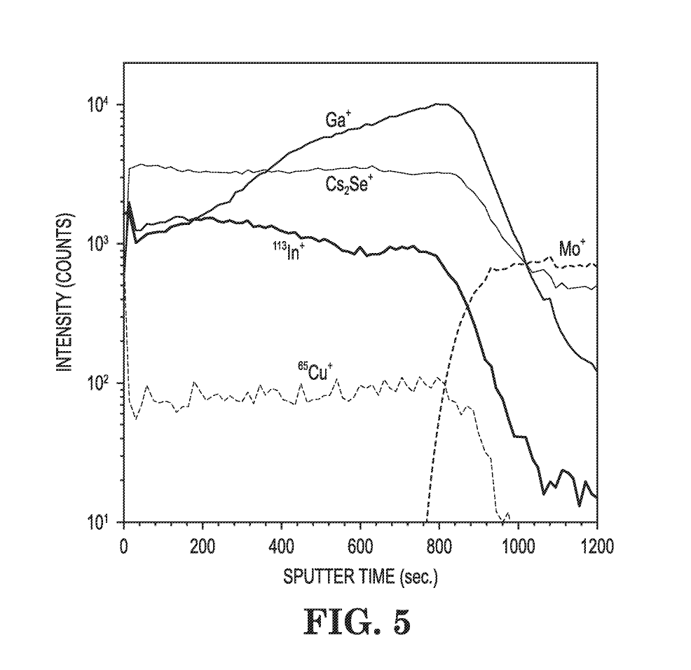

A CIGS photovoltaic light absorber was prepared by selenization of a photovoltaic light-absorber precursor having a sub-stoichiometric amount of Se deposited onto a back electrode that did not substantially include aluminum. Onto a 5″×5″ piece of 2 mil 430-type stainless steel foil, a 1000 nm thick layer of Mo was deposited by DC sputtering from an elemental target under 4.5 mtorr of Ar at 150 W. Next, a thin layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor, after which it was cooled to room temperature. FIG. 4 shows Co K-alpha x-ray diffraction (XRD) data of the stack after the selenization step in the region of chalcopyrite diffraction peak associated with the crystallographic Miller index {hkl}={112}. FIG. 5 shows secondary ion mass spectroscopy (SIMS) depth profiles for several elemental species as the stack was sputtered using a Cs ion beam. In FIG. 5, the x-axis (i.e. “sputtering time”) can be related to the position in the stack below the top surface. The signal for Al⁺ does not appear in FIG. 5 because it is below the lower limit of intensity plotted (i.e. 10 counts).

### Example 1

A CIGAS photovoltaic light absorber was prepared by selenization of a photovoltaic light-absorber precursor having a sub-stoichiometric amount of Se deposited onto a back electrode that included a layer deposited by co-sputtering aluminum and molybdenum. Onto a 5″×5″ piece of 2 mil 430-type stainless steel foil, a 1000 nm thick layer of Mo was deposited by DC sputtering from an elemental target under 4.5 mtorr of Ar at 150 W. Next, a 50 nm layer of approximately 15 at % Al and 85 at % Mo was deposited by co-sputtering from elemental targets. Simultaneously, Al was deposited by DC sputtering at 30 W and Mo was deposited by RF sputtering at 143 W under 9.75 mtorr of Ar. Next, a thin layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor, after which it was cooled to room temperature. FIG. 4 shows Co K-alpha x-ray diffraction (XRD) data of the stack after the selenization step in the region of chalcopyrite diffraction peak associated with the crystallographic Miller index {hkl}={112}. As compared to that of Comparative Example A, the diffraction data of Example 1 shows increased intensity at higher diffraction angles (i.e. two-theta) signifying a distortion of the crystal structure due to Al incorporation into and chalcopyrite lattice.

### Example 2

A CIGAS photovoltaic light absorber was prepared by selenization of a photovoltaic light-absorber precursor having a sub-stoichiometric amount of Se deposited onto a back electrode that included a layer deposited by co-sputtering aluminum and molybdenum. Onto a 5″×5″ piece of 2 mil 430-type stainless steel foil, a 1000 nm thick layer of Mo was deposited by DC sputtering from an elemental target under 4.5 mtorr of Ar at 150 W. Next, a 150 nm layer of approximately 15 at % Al and 85 at % Mo was deposited by co-sputtering from elemental targets. Simultaneously, Al was deposited by DC sputtering at 30 W and Mo was deposited by RF sputtering at 143 W under 9.75 mtorr of Ar. Next, a thin layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor, after which it was cooled to room temperature. FIG. 4 shows Co K-alpha x-ray diffraction (XRD) data of the stack after the selenization step in the region of chalcopyrite diffraction peak associated with the crystallographic Miller index {hkl}={112}. As compared to that of Comparative Example A, the diffraction data of Example 2 shows increased intensity at higher diffraction angles (i.e. two-theta) signifying a distortion of the crystal structure due to Al incorporation into and chalcopyrite lattice.

### Example 3

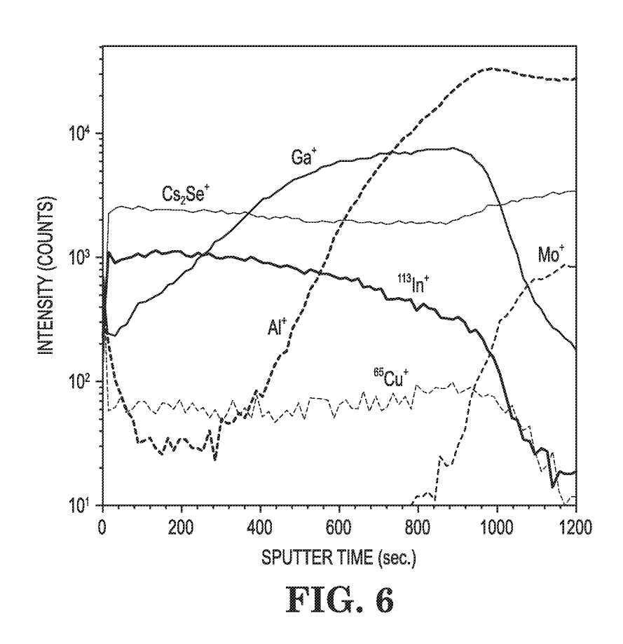

A CIGAS photovoltaic light absorber was prepared by selenization of a photovoltaic light-absorber precursor having a sub-stoichiometric amount of Se deposited onto a back electrode that included a layer deposited by co-sputtering aluminum and molybdenum. Onto a 5″×5″ piece of 2 mil 430-type stainless steel foil, a 1000 nm thick layer of Mo was deposited by DC sputtering from an elemental target under 4.5 mtorr of Ar at 150 W. Next, a 400 nm layer of approximately 15 at % Al and 85 at % Mo was deposited by co-sputtering from elemental targets. Simultaneously, Al was deposited by DC sputtering at 30 W and Mo was deposited by RF sputtering at 143 W under 9.75 mtorr of Ar. Next, a thin layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor, after which it was cooled to room temperature. FIG. 4 shows Co K-alpha x-ray diffraction (XRD) data of the stack after the selenization step in the region of chalcopyrite diffraction peak associated with the crystallographic Miller index {hkl}={112}. As compared to that of Comparative Example A, the diffraction data of Example 3 shows increased intensity at higher diffraction angles (i.e. two-theta) signifying a distortion of the crystal structure due to Al incorporation into and chalcopyrite lattice. FIG. 6 shows secondary ion mass spectroscopy (SIMS) depth profiles for several elemental species as the stack was sputtered using a Cs ion beam. In FIG. 6, the x-axis (i.e. “sputtering time”) can be related to the position in the stack below the top surface. As compared to that of Comparative Example A, the SIMS data for Example 3 shows a significant aluminum concentration throughout the light absorber layer due to diffusion of aluminum from the back electrode layer. Furthermore, the SIMS data for Example 3 shows that the concentration of aluminum is at a minimum within at interior region of the absorber layer.

### Comparative Example B

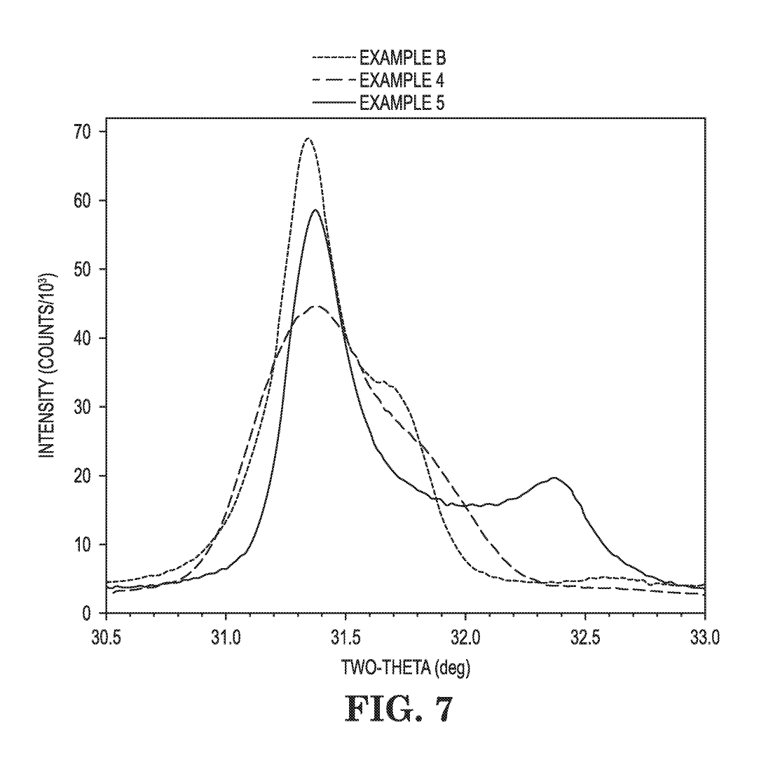

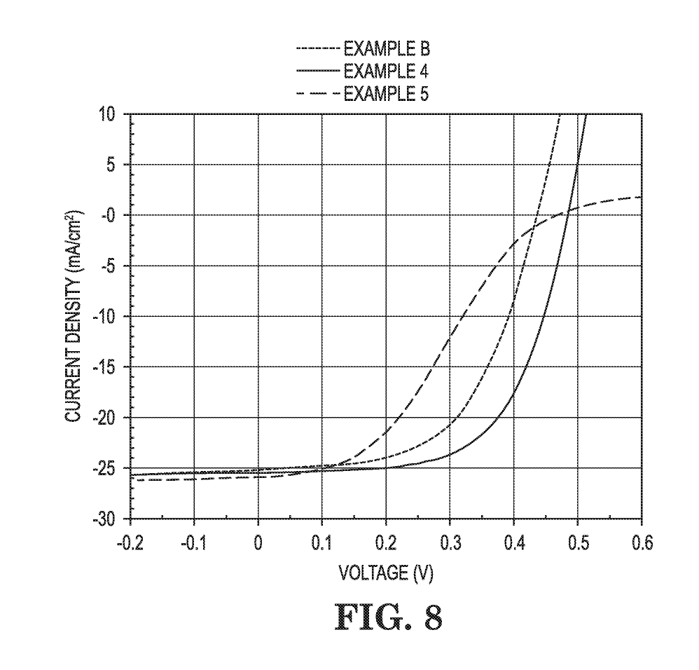

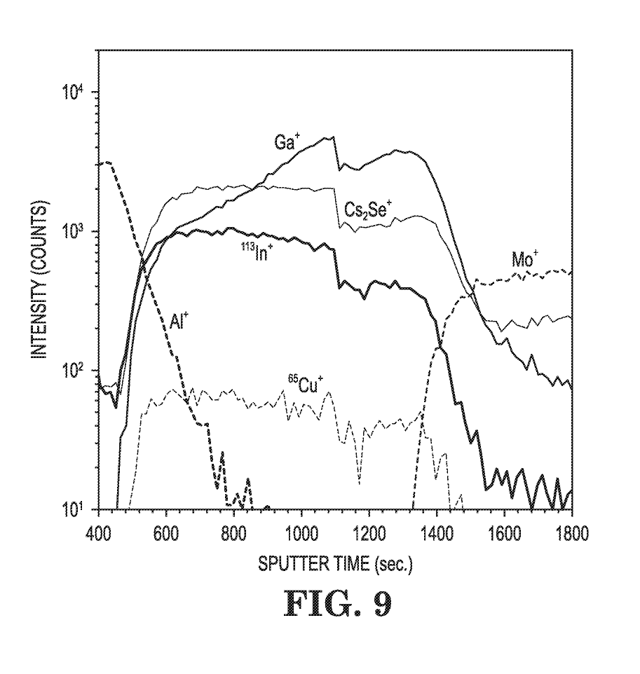

A photovoltaic device with a CIGS photovoltaic light absorber was prepared by selenization of a photovoltaic light-absorber precursor having a sub-stoichiometric amount of Se deposited onto a back electrode that did not substantially include aluminum. Onto a 5″×5″ piece of 2 mil 430-type stainless steel foil, a 600 nm thick layer of Mo was deposited by DC sputtering from an elemental target under 4.5 mtorr of Ar at 150 W. Next, layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor. Next, a thin CdS layer was deposited by a chemical bath technique from cadmium sulfate and thiourea in ammonium hydroxide and water. Next, a layer of electrically resistive aluminum doped zinc oxide (RAZO) and a layer of indium tin oxide (ITO) were deposited by DC sputtering. Finally, a metallic collection grid was evaporated onto the device and the sample was scribed to define a device with an active area of 0.43 cm². The device was analyzed by current-voltage (IV), x-ray diffraction (XRD), and secondary ion mass spectroscopy (SIMS). FIG. 7 shows Co K-alpha x-ray diffraction (XRD) data of the stack after the selenization step in the region of chalcopyrite diffraction peak associated with the crystallographic Miller index {hkl}={112}. FIG. 8 shows current-voltage (IV) data of the device under AM1.5 illumination. The device had a power conversion efficiency of 6.32%, an open circuit voltage (Voc) of 435 mV, a short circuit current density (Jsc) of 25.15 mA/cm², and a fill factor (FF) of 56.81%. FIG. 9 shows secondary ion mass spectroscopy (SIMS) depth profiles for several elemental species as the device was sputtered using a Cs ion beam. In FIG. 9, the x-axis (i.e. “sputtering time”) can be related to the position in the device below the top surface.

### Example 4

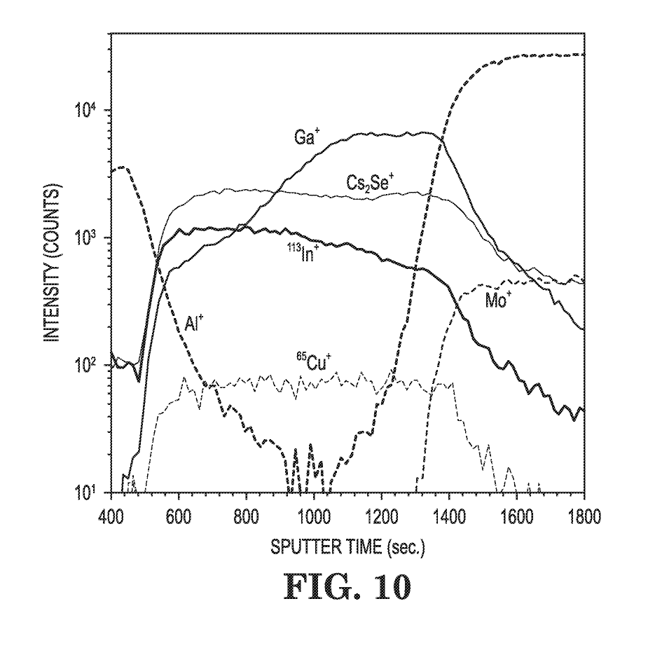

A photovoltaic device with a CIGAS photovoltaic light absorber was prepared by selenization of a photovoltaic light absorber precursor having a sub-stoichiometric amount of Se deposited onto a back electrode that that included a layer deposited by co-sputtering aluminum and molybdenum. Onto a 5″×5″ piece of 2 mil 430-type stainless steel foil, a 600 nm thick layer of Mo was deposited by DC sputtering from an elemental target under 4.5 mtorr of Ar at 150 W. Next, a 400 nm layer of approximately 15 at % Al and 85 at % Mo was deposited by co-sputtering from elemental targets. Simultaneously, Al was deposited by DC sputtering at 30 W and Mo was deposited by RF sputtering at 150 W under 9.75 mtorr of Ar. Next, a thin layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor. Next, a thin CdS layer was deposited by a chemical bath technique from cadmium sulfate and thiourea in ammonium hydroxide and water. Next, a layer of electrically resistive aluminum doped zinc oxide (RAZO) and a layer of indium tin oxide (ITO) were deposited by DC sputtering. Finally, a metallic collection grid was evaporated onto the device and the sample was scribed to define a device with an active area of 0.43 cm². The device was analyzed by current-voltage (IV), x-ray diffraction (XRD), and secondary ion mass spectroscopy (SIMS). FIG. 7 shows Co K-alpha x-ray diffraction (XRD) data of the stack after the selenization step in the region of chalcopyrite diffraction peak associated with the crystallographic Miller index {hkl}={112}. FIG. 8 shows current-voltage (IV) data of the device under AM1.5 illumination. The device had a power conversion efficiency of 7.71%, an open circuit voltage (Voc) of 484 mV, a short circuit current density (Jsc) of 25.51 mA/cm², and a fill factor (FF) of 61.59% all of which are improved over Comparative Example B. FIG. 10 shows secondary ion mass spectroscopy (SIMS) depth profiles for several elemental species as the device was sputtered using a Cs ion beam. In FIG. 10, the x-axis (i.e. “sputtering time”) can be related to the position in the device below the top surface. As compared to that of Comparative Example B, the SIMS data for Example 4 shows a significant aluminum concentration throughout the light absorber layer due to diffusion of aluminum from the back electrode layer. Furthermore, the SIMS data for Example 4 shows that the concentration of aluminum is at a minimum within at interior region of the absorber layer.

### Example 5

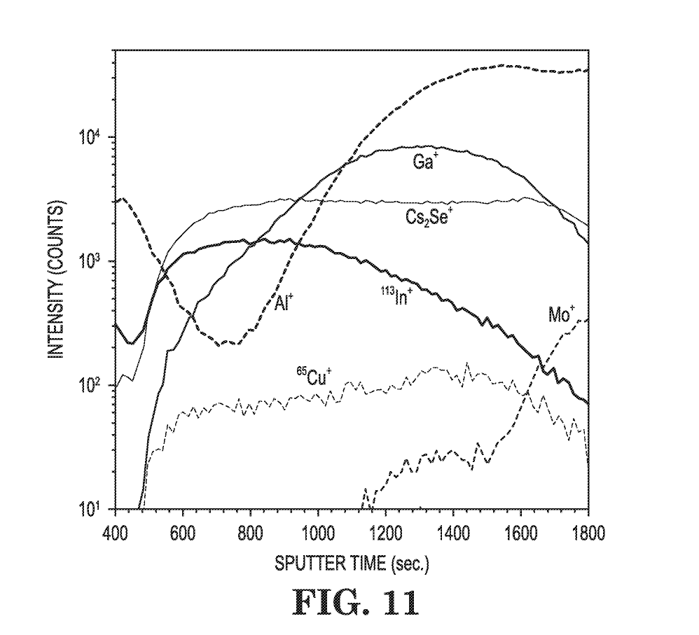

A photovoltaic device with a CIGAS photovoltaic light absorber was prepared by selenization of a photovoltaic light absorber precursor having a sub-stoichiometric amount of Se deposited onto a back electrode that that included a layer deposited by co-sputtering aluminum and molybdenum. Onto a 5″×5″ piece of 2 mil 430-type stainless steel foil, a 600 nm thick layer of Mo was deposited by DC sputtering from an elemental target under 4.5 mtorr of Ar at 150 W. Next, a 150 nm layer of approximately 50 at % Al and 50 at % Mo was deposited by co-sputtering from elemental targets. Simultaneously, Al was deposited by DC sputtering at 85 W and Mo was deposited by RF sputtering at 105 W under 9.75 mtorr of Ar. Next, thin layer of sodium fluoride was deposited by thermal evaporation. Next, a sub-stoichiometric precursor layer was deposited by sputtering from In, Cu—Ga, and Cu—In—Ga targets in the presence of selenium vapor. The stack then underwent a 10 min selenization step at 575° C. in an atmosphere of 1 mtorr Se vapor. Next, a thin CdS layer was deposited by a chemical bath technique from cadmium sulfate and thiourea in ammonium hydroxide and water. Next, a layer of electrically resistive aluminum doped zinc oxide (RAZO) and a layer of indium tin oxide (ITO) were deposited by DC sputtering. Finally, a metallic collection grid was evaporated onto the device and the sample was scribed to define a device with an active area of 0.43 cm². The device was analyzed by current-voltage (IV), x-ray diffraction (XRD), and secondary ion mass spectroscopy (SIMS). FIG. 7 shows Co K-alpha x-ray diffraction (XRD) data of the stack after the selenization step in the region of chalcopyrite diffraction peak associated with the crystallographic Miller index {hkl}={112}. FIG. 8 shows current-voltage (IV) data of the device under AM1.5 illumination. The device had a power conversion efficiency of 4.42%, an open circuit voltage (Voc) of 463 mV, a short circuit current density (Jsc) of 25.89 mA/cm², and a fill factor (FF) of 36.82%. Both the Voc and Jsc of Example 5 are improved over Comparative Example B. FIG. 11 shows secondary ion mass spectroscopy (SIMS) depth profiles for several elemental species as the device was sputtered using a Cs ion beam. In FIG. 11, the x-axis (i.e. “sputtering time”) can be related to the position in the device below the top surface. As compared to that of Comparative Example B, the SIMS data for Example 5 shows a significant aluminum concentration throughout the light absorber layer due to diffusion of aluminum from the back electrode layer. Furthermore, the SIMS data for Example 5 shows that the concentration of aluminum is at a minimum within at interior region of the absorber layer.

1. A photovoltaic device comprising:
a) a substrate;
b) a first electrode located over the substrate;
c) at least one chalcogenide-containing photovoltaic light-absorber located over and electrically connected to the first electrode; wherein the chalcogenide-containing photovoltaic light-absorber has a composition profile defined by at least a first region, a second region, and a third region; wherein the first region is located proximal to the first electrode, the second region is located between the first region and the third region, and the third region is located distal to the first electrode; wherein each region of the chalcogenide-containing photovoltaic light-absorber comprises Cu, In, Ga, Al, and at least one chalcogen; and wherein the concentration of Al present in the second region is less than the concentration of Al present in each of the first region and third region;
d) an n-type semiconductor region located over the at least one chalcogenide-containing photovoltaic light-absorber; and
e) a second electrode located over the n-type semiconductor region.

2. The photovoltaic device according to claim 1, wherein the at least one chalcogen is chosen from Se, S, Te, and combinations thereof.

3. The photovoltaic device according to claim 1, wherein the chalcogenide-containing photovoltaic light-absorber comprises Ga in an amount of at least 0.4 atomic percent based on the total chalcogenide-containing photovoltaic light-absorber.

4. The photovoltaic device according to claim 1, wherein the at least one chalcogenide-containing photovoltaic light-absorber in the first region is represented by the chemical formula Cua1Inb1Gac1Ald1Sew1Sx1Tey1Naz1, wherein 0.75≤a1≤1.10, 0.00≤b1≤0.84, 0.15≤c1≤0.70, 0.01≤d1≤0.35, 0.00≤w1≤3.00, 0.00≤x1≤3.00, 0.00≤y1≤3.00, 0.00≤z1≤0.05, b1+c1+d1=1, and 1.00≤w1+x1+y1≤3.00; wherein the at least one chalcogenide-containing photovoltaic light-absorber in the second region is represented by the chemical formula Cua2Inb2Gac2Ald2Sew2Sx2Tey2Naz2, wherein 0.75≤a2≤1.10, 0.00≤b2≤0.97, 0.02≤c2≤0.70, 0.01≤d2≤0.35, 0.00≤w2≤3.00, 0.00≤x2≤3.00, 0.00≤y2≤3.00, 0.00≤z2≤0.05, b2+c2+d2=1, and 1.00≤w2+x2+y2≤3.00; wherein the at least one chalcogenide-containing photovoltaic light-absorber in the third region is represented by the chemical formula Cua3Inb3Gac3Ald3Sew3Sx3Tey3Naz3, wherein 0.75≤a3≤1.10, 0.35≤b3≤0.97, 0.02≤c3≤0.30, 0.01≤d3≤0.35, 0.00≤w3≤3.00, 0.00≤x3≤3.00, 0.00≤y3≤3.00, 0.00≤z3≤0.05, b3+c3+d3=1, and 1.00≤w3+x3+y3≤3.00; wherein d2<d1; and wherein d2<d3.

5. The photovoltaic device according to claim 4, wherein c1>c2>c3.

6. The photovoltaic device according to claim 1, wherein the at least one chalcogenide-containing photovoltaic light-absorber has a total thickness (T), the first region has a thickness (t1), the second region has a thickness (t2), and the third region has a thickness (t3); wherein T is in the range from 0.25 to 5.00 micrometers; wherein 0.1*T≤t1; wherein 0.1*T≤t2≤0.8*T; and wherein 0.1*T≤t3.

7. The photovoltaic device according to claim 1, wherein the composition profile defines a bandgap profile, wherein the first region has a bandgap value in the range from 1.09 to 1.96 eV, the second region has a bandgap value in the range from 1.02 to 1.96 eV, and the third region has a bandgap value in the range from 1.02 to 1.67 eV.

8. The photovoltaic device according to claim 1, wherein the first electrode comprises one or more layers that contain a material chosen from Mo, W, Nb, Ta, Cr, Ti, Al, nitrides thereof, and combinations thereof.

9. The photovoltaic device according claim 1, wherein the n-type semiconductor region comprises a buffer region comprising one or more layers that include at least one first element chosen from Cd and Zn, and at least one second element chosen from S, Se, O, and combinations thereof.

10. The photovoltaic device according to claim 1, wherein the second electrode comprises at least one layer that includes a material chosen from zinc oxide, aluminum-doped zinc oxide, indium tin oxide, and combination thereof.

11. A method of processing a chalcogenide-containing photovoltaic light-absorber or a photovoltaic light-absorber precursor, comprising the steps of:
a) providing a stack comprising:
i) a substrate;
ii) a first electrode precursor located over the substrate, wherein the first electrode precursor includes at least one layer comprising aluminum; and
iii) at least one layer located over the first electrode precursor, wherein the at least one layer comprises a chalcogenide-containing photovoltaic light-absorber comprising copper, indium, gallium, and at least one chalcogen, or a photovoltaic light-absorber precursor comprising copper, indium, gallium, and optionally a sub-stoichiometric amount of at least one chalcogen; and
b) a heating step comprising heating the stack to diffuse at least a portion of the aluminum into the at least one layer of the absorber or the absorber precursor.

12. The method according to claim 11, wherein the heating step comprises heating the stack to a temperature in the range from 50° C. to 650° C., wherein the stack is at a temperature in the range from 50° C. to 650° C. for a time period in the range from 1 to 90 minutes.

13. The method according to claim 11, wherein the heating step is a first heating step, and further comprising a second heating step comprising heating the stack in the presence of at least one chalcogen to convert at least a portion of the photovoltaic light-absorber precursor into a chalcogenide-containing photovoltaic light-absorber, wherein the chalcogenide-containing photovoltaic light-absorber has a composition profile defined by at least a first region, a second region, and a third region, wherein the second region is located between the first region and the third region, wherein each region of the chalcogenide-containing photovoltaic light-absorber comprises Cu, In, Ga, Al, and at least one chalcogen, and wherein the concentration of Al in the second region is less than the concentration of Al in each of the first region and third region.

14. The method according to claim 13, wherein the second heating step comprises heating the stack to a temperature in the range from 450° C. to 650° C., wherein the stack is at a temperature in the range from 450° C. to 650° C. for a time period in the range from 1 to 90 minutes.

15. The method according to claim 13, wherein the first and second heating steps are performed sequentially, simultaneously, or in an overlapping manner.

16. The method according to claim 13, further comprising, after the second heating step, heating the stack to diffuse an additional amount of the aluminum into the at least one layer of the absorber.

17. The method according to claim 11, wherein forming the first electrode precursor over the substrate comprises co-sputtering Al with a material chosen from Mo, W, Nb, Ta, Cr, Ti, nitrides thereof, and combinations thereof.
